(19) United States
(12) Patent Application Publication
(10) Pub. No.: US 2026/0114247 A1
(43) Pub. Date: Apr. 23, 2026

(54) FABRICATION METHODS OF SEMICONDUCTOR STRUCTURES

(71) Applicant: Semiconductor Manufacturing International (Shanghai) Corporation, Shanghai (CN)

(72) Inventor: Jisong JIN, Shanghai (CN)

(21) Appl. No.: 19/363,115

(22) Filed: Oct. 20, 2025

(30) Foreign Application Priority Data
Oct. 18, 2024 (CN) 202411466057.0

(51) Int. Cl. H01L 21/033; H01L 21/311; H01L 21/3115; H10B 10/00

(52) U.S. Cl. CPC H10P 76/4085; H10B 10/12; H10P 30/40; H10P 50/283; H10P 50/73; H10P 76/405; H10B 10/18

(57) ABSTRACT

A semiconductor fabrication method includes providing a base containing a first area and a second area; modifying a second core material layer in the second area to form a third core material layer having an etching selectivity ratio with the second core material layer; forming a first core material layer; patterning the first core material layer and forming first core layers; forming first spacers; patterning the second and third core material layers in the second area and forming second and third core layers; forming second spacers; forming a third protective layer; patterning the third core layers through the third protective layer; patterning a target material layer through the second spacers and the third core layers and forming first and second target structures. Pitch of adjacent first target structures is less than or equal to that of adjacent second target structures. SAQP and SALELE processes are performed over the same base.

### CROSS-REFERENCE TO RELATED APPLICATION

This application claims the priority of Chinese Patent Application No. CN 202411466057.0, filed on October 18, 2024, the entire content of which is incorporated herein by reference.

### FIELD OF THE DISCLOSURE

The present disclosure generally relates to the field of semiconductor fabrication technology and, more particularly, relates to fabrication methods of a semiconductor structure.

### BACKGROUND

With the rapid advance of semiconductor manufacturing technologies, semiconductor devices are developing towards higher component density and higher integration. Photolithography technology is a commonly used patterning method and the most critical production technology in semiconductor manufacturing processes. Along with continuous reduction of pattern critical dimension (CD) and pitch, self-aligned double patterning (SADP) can no longer meet current process requirements, and self-aligned quadruple patterning (SAQP) method comes into being. Generally, the minimum pitch that SADP can form with the deep ultraviolet (DUV) technology is about half of the pitch limit of 76 nm for a single DUV exposure, which is a pitch of 38 nm. As such, the limit of SAQP with the DUV technology is a pitch of 19 nm. When a good yield is ensured, the general SADP limit is around 40 nm, and the SAQP limit is around 24 nm. In the back-end process, the SADP or SAQP process is often not used to form metal patterns, while self-aligned litho-etch litho-etch or spacer assisted litho-etch litho-etch (SALELE) is often used. SALELE has the advantage of more design freedom than SADP, but the metal pitch limit is similar to SADP, and the minimum pitch can only be about 40 nm.

However, as the size of transistors and chips shrinks, the back-end metal pitch also needs to reach a value of smaller than 40 nm to 30 nm or even a smaller pitch. The traditional SAQP method can achieve smaller pitches, but like SADP, it has major limitations in metal line layout design. Metal line layout generally needs to take into account both smaller pitches and large pitches on the same chip, as well as design freedom such as freely placed metal line positions, which is difficult to achieve using purely the SAQP process. However, in the absence of extreme ultraviolet (EUV) exposure processing, it is relatively difficult to achieve both pitch reduction and design freedom through the SAQP process that only uses the DUV lithography. It also has great limitations on production of chips with more advanced processes.

### SUMMARY OF THE DISCLOSURE

The problem solved by embodiments of the present disclosure is to provide a method for forming a semiconductor structure, thereby improving the design freedom in the patterning process. Other aspects of the present disclosure can be understood by those skilled in the art in light of the description, the claims, and the drawings of the present disclosure.

To solve the above problems, embodiments of the present disclosure provide a method for forming a semiconductor structure. The method includes providing a base, wherein the base includes a substrate and a target material layer on the substrate, a second core material layer is formed over the base, the base further includes a first area for forming first target structures and a second area for forming second target structures, both the first target structure and the second target structure extend along a first direction, and a pitch between adjacent first target structures is smaller than or equal to a pitch between adjacent second target structures; forming a first protective layer covering the second core material layer in the first area; modifying the second core material layer in the second area with the first protective layer as a mask to form a third core material layer having an etching selectivity ratio with the remaining second core material layer in the first area; removing the first protective layer; forming a first core material layer covering the second core material layer and the third core material layer; patterning the first core material layer to form first core layers being separated in the first area, wherein the first core layers extend along the first direction and are arranged in parallel along the second direction, and the first direction is perpendicular to the second direction; forming first spacers covering sidewalls of the first core layers; removing the first core layers; forming a second protective layer on the third core material layer, wherein separate second protective layer openings extending along the first direction and arranged in parallel along the second direction are formed in the second protective layer; patterning the second core material layer and the third core material layer using the first spacers and the second protective layer as a mask and forming second core layers corresponding to the second core material layer, third core layers corresponding to the third core material layer, and third core layer openings corresponding to the second protective layer openings in the third core layer; removing the first spacers and the second protective layer; forming second spacers covering sidewalls of the second core layers and the third core layers; forming a third protective layer to cover the second core layers, the third core layers, and the second spacers, wherein separate third protective layer openings extending along the first direction and arranged in parallel along the second direction are formed in the third protective layer, the third protective layer fills the third core layer openings, and the third protective layer openings expose the third core layers; patterning the third core layers using the third protective layer as a mask; removing the third protective layer; removing the second core layers; and patterning the target material layer using the second spacers and the third core layers as a mask and forming the first target structures in the first area and the second target structures in the second area.

Compared with the prior art, the technical solution of embodiments of the present disclosure has the following advantages:

In the formation method provided by embodiments of the present disclosure, the base includes the first area for forming the first target structures, and the second area for forming the second target structures. The pitch of adjacent first target structures is less than or equal to the pitch of adjacent second target structures. The target material layer is patterned with the second spacers and third core layers as a mask to form the first target structures in the first area and the second target structures in the second area. In embodiments of the present disclosure, for the first area, the first spacers covering sidewalls of the first core layers are formed, the second core material layer is patterned with the first spacers as a mask, separate second core layers are formed in the first area, the second spacers covering sidewalls of the second core layers are formed, and the target material layer is patterned with the second spacers as a mask. SAQP is used in the above processes. The SAQP process may form the first target structures with a smaller pitch. For the second area, the second core material layer in the second area is modified to transform the second core material layer into the third core material layer having an etching selectivity ratio with the second core material layer, the third core material layer in the second area is patterned using the second protective layer as a mask, the third core layers are formed, the second spacers covering sidewalls of the third core layers are formed, the third core layers are patterned with the third protective layer, and the target material layer is patterned with the second spacers and the third core layers as a mask after the third core layers are patterned. SALELE is used in the above processes and the second target structures are formed with a larger pitch. As such, the SAQP and the SALELE processes are integrated. The first target structures with a smaller pitch and the second target structures with a larger pitch are formed over the same base, which is conducive to meeting more semiconductor process requirements through process integration and improving the design freedom in patterning processes.

### BRIEF DESCRIPTION OF THE DRAWINGS

The following drawings are merely examples for illustrative purposes according to various disclosed embodiments and are not intended to limit the scope of the present disclosure.

FIGS. 1-38 illustrate schematic structural diagrams corresponding to steps in methods for forming a semiconductor structure according to various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

As mentioned in the background section, the SALELE process is a common solution in back-end patterning. The process has two core values in patterning. The first value is the spacing between metal lines defined by two lithographies is determined by the thickness of the spacer during the process. The spacer is usually formed by an atomic layer deposition (ALD) process with very high uniformity. As such, the overlay of two lithographies does not cause a change of spacing between two adjacent metal lines. It also makes the spacing between metal lines very uniform and fixed, and opens a large process window for reliability tests such as time dependent dielectric breakdown (TDDB) and breakdown voltage (VBD). The second value is that the tip to tip of the metal lines defined by two lithographies may be formed very small by using cuts of patterning produced by other masks. Further, a cut corresponding to the first lithography and a cut corresponding to the second lithography may not interfere with each other. This is also called a self-aligned block process in the industry.

The above two advantages are the reason that SALELE not only balances the process difficulty at the back-end patterning, but also provides great design freedom. The SALELE process also has various similar solutions, such as that shown in CN111640668B and process solutions disclosed in US10991596B2.

In general, the minimum pitch created by immersion DUV (ArFi) in a single photolithography is about 80 nm. Thus, SALELE may use DUV equipment to achieve a minimum pitch of 38 nm to 40 nm, while more advanced chips require smaller pitches, such as 32 nm, 28 nm, 24 nm, etc.

With the traditional fin patterning, when a pitch reaches about 30 nm, the SAQP process may be used. Because SADP may only make a fin pattern with a minimum pitch of 38 nm, SADP needs to be repeated to become SAQP. The SAQP process may well meet the needs of fin patterning. Because fin patterns are relatively regular, the fin pitches in an area of a chip are generally fixed and regular, and the difference between areas is not very large. However, the SAQP solution has great limitations in the back-end process where metal lines have a high degree of freedom. For example, when metal patterns of SRAM are formed, metal lines formed by patterning are difficult to match patterns of the first metal layer of the traditional SRAM. Further, the width of metal lines formed by SAQP is relatively fixed, which also makes designs of other bypass circuits more difficult.

As such, currently for back-end patterning in semiconductor structures of the same area, it is difficult to achieve both smaller pitch and design freedom, meet more requirements of semiconductor processes, and improve design freedom in patterning processes correspondingly.

In order to solve the above technical problems, embodiments of the present invention provide a method for forming a semiconductor structure. The method includes providing a base, wherein the base contains a substrate and a target material layer on the substrate, a second core material layer is formed over the base, the base further includes a first area for forming first target structures, and a second area for forming second target structures, the first target structures and the second target structures all extend along a first direction, and a pitch of adjacent first target structures is less than or equal to a pitch of adjacent second target structures; forming a first protective layer covering the second core material layer in the first area; modifying the second core material layer in the second area using the first protective layer as a mask and forming a third core material layer having an etching selectivity ratio with the remaining second core material layer in the first area; removing the first protective layer; forming a first core material layer covering the second core material layer and the third core material layer; patterning the first core material layer and forming separate first core layers in the first area, wherein the first core layers extend along the first direction and are arranged in parallel along the second direction, and the first direction is perpendicular to the second direction; forming first spacers covering sidewalls of the first core layers; removing the first core layers; forming a second protective layer on the third core material layer in the second area, wherein separate second protective layer openings extending along the first direction and arranged in parallel along the second direction are formed in the second protective layer; patterning the second core material layer and the third core material layer using the first spacers and the second protective layer as a mask and forming second core layers corresponding to the second core material layer, third core layers corresponding to the third core material layer, and third core layer openings corresponding to the second protective layer openings in the third core layers; removing the first spacers and the second protective layer; forming second spacers covering sidewalls of the second core layers and the third core layers; forming a third protective layer to cover the second core layers, the third core layers, and the second spacers, wherein separate third protective layer openings extending along the first direction and arranged in parallel along the second direction are formed in the third protective layer, the third protective layer fills the third core layer openings, and the third protective layer openings expose the third core layers; patterning the third core layers using the third protective layer as a mask; removing the third protective layer; removing the second core layers; and patterning the target material layer using the second spacers and the third core layers as a mask and forming the first target structures in the first area and the second target structures in the second area.

In embodiments of the present disclosure, for the first area, the first spacers are formed to cover sidewalls of the first core layers, the first spacers are used as a mask to pattern the second core material layer in the first area, separate second core layers in the first area are formed, the second spacers are formed to cover sidewalls of the second core layers, and the second spacers are used as a mask to pattern the target material layer. SAQP is used in the above processes. The SAQP process may form the first target structures with a smaller pitch. For the second area, the second core material layer in the second area is modified to convert part of the second core material layer into the third core material layer having an etching selectivity ratio with the second core material layer, the third core material layer in the second area is patterned with the second protective layer to form the third core layers, the second spacers covering sidewalls of the third core layers are formed, the third core layers are patterned using the third protective layer, and the second spacers and the third core layers are used as a mask to pattern the target material layer after the third core layers are patterned. SALELE is used in the above processes. The SALELE process may form the second target structures with a larger pitch. Embodiments of the present invention may better integrate the SAQP process and the SALELE process, and form the first target structures with a smaller pitch and the second target structures with a larger pitch over the same base. It is conducive to meeting more semiconductor process requirements through process integration and improving the design freedom in patterning processes.

In order to make the above-mentioned objects, features and advantages of the present disclosure more obvious and easy to understand, various embodiments are described in detail below in conjunction with the accompanying drawings.

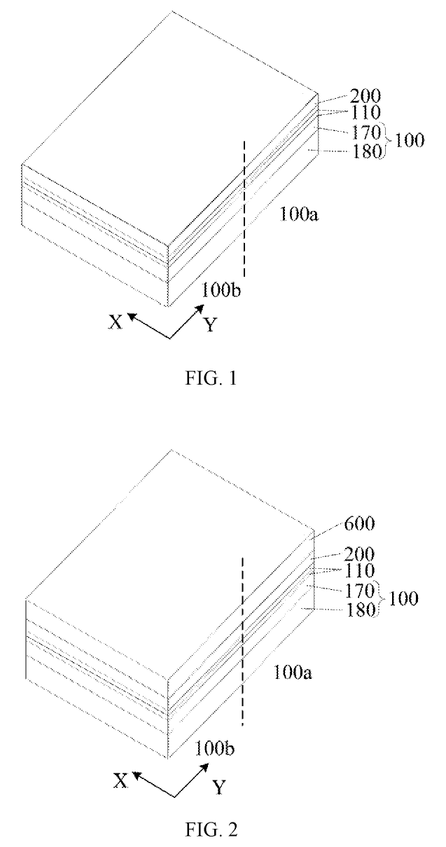

FIGS. 1 to 38 are schematic structural diagrams corresponding to steps of methods for forming a semiconductor structure according to embodiments of the present disclosure

Referring to FIG. 1, a base 100 is provided. The base 100 includes a substrate 180 and a target material layer 170 on the substrate 180. A second core material layer 200 is formed over the base 100. The base 100 includes a first area 100a for forming first target structures and a second area 100b for forming second target structures. Both the first target structure and second target structure extend along a first direction (i.e., the X direction in FIG. 1). The pitch of adjacent first target structures is smaller than or equal to the pitch of adjacent second target structures.

The base 100 provides a process operation basis for formation processes of semiconductor structures. Exemplarily, the semiconductor structures include metal interconnection lines, barrier layers, adhesion layers, cap layers, etc.

In some embodiments, the substrate 180 may be a wafer on which transistors and part of connection lines are formed.

In some embodiments, the base 100 includes the first area 100a used for forming multiple first target structures and a second area 100b used for forming multiple second target structures. The pitch of adjacent first target structures is smaller than or equal to the pitch of adjacent second target structures.

In some embodiments, during formation processes of a semiconductor structure, it is necessary to form denser first target structures and sparser second target structures. For example, the pitch of adjacent first target structures is smaller than or equal to the pitch of adjacent second target structures. The SAQP process may be used to form denser target structures. However, it is hard to use SAQP to create sparser target structures. In addition, the pitch between target structures is relatively fixed and difficult to adjust freely according to layout needs. When the SALELE process is used, the pitch between target structures may be defined according to the layout. Further, the pitch is easy to adjust, and a self-aligned block process may be realized. However, it is difficult to use SALELE to form denser (e.g., a pitch smaller than 38 nm) target structures. In some embodiments, the SAQP process is used in the first area 100a, and the SALELE process is used in the second area 100b. As such, the base 100 including the first area 100a for forming the first target structures and the second area 100b for forming the second target structures indicates the following may be achieved in some embodiments: Fabricating the first target structures with smaller pitches that are difficult to make with the SALELE process and fabricating the second target structures with larger pitches that are difficult to make with the SAQP process and having more freedom in design over the same base 100 (e.g., a same wafer).

In some embodiments, the first area 100a includes a logic device area. The second area 100b includes a peripheral device area. The logic device area has denser patterns, and the peripheral device area has sparser patterns. Optionally, the logical device area includes device areas containing a central processing unit (CPU) and a graphics processing unit (GPU), and the peripheral device area includes device areas containing static random-access memory (SRAM), input and output (IO) devices, etc.

Optionally, the pitch of adjacent first target structures is 24 nm to 38 nm and the pitch of adjacent second target structures is 38 nm to 200 nm.

Thus, the SAQP process may be used to form the first target structures, and the SALELE process may be used to form the second target structures. The first target structures with a pitch of 24 nm to 38 nm and the second target structures with a pitch of 38 nm to 200 nm may be formed over the same base 100.

In some embodiments, the thickness of gate oxide layers in the logic device area is smaller than the thickness of gate oxide layers in the peripheral device area. Generally, the operating voltage of CPU or GPU transistors is lower than that of transistors in the IO device area. For example, the operating voltage of CPU transistors may be 0.75 V, while the operating voltage of transistors in an IO device area may be 1.2 V or even 1.8 V. Usually, in order to maintain the reliability and electrical performance of transistors in an IO device area, the gate oxide layer of transistors in the IO device area may be thicker than that in a logic device area. The thickness difference mainly comes from the thickness of a high-K (HK) dielectric layer of a high-K metal gate (HKMG) and the thickness of an interface layer (e.g., a silicon oxide layer) between transistor channels. Optionally, the interface layer in a gate oxide layer of the logic device area is thinner than that in the IO device area, and the HK dielectric layers over the interface layer in the two areas have the same thickness. The interface layer and HK dielectric layer together form a gate dielectric layer of a corresponding transistor. Thus, the thickness of a gate oxide layer in the logic device area is smaller than that in the peripheral device area.

The target material layer 170 is used to provide a process platform for forming the first target structures and the second target structures.

In some embodiments, in the step of providing the base 100, the target material layer 170 is a dielectric layer, the first target structures are first trenches, and the second target structures are second trenches.

The first trench and second trench provide spatial locations for subsequent processes. The target material layer 170 is a dielectric layer used to separate structures formed in the first trench and second trench.

In some embodiments, materials of the dielectric layer include one or more of silicon oxide, silicon nitride, silicon oxynitride, silicon oxycarbide, silicon carbonitride, silicon oxynitride, a low-K (LK) material (e.g., a material of an LK dielectric layer), and an ultralow-K (ULK) material (e.g., a material of an ULK dielectric layer).

In some embodiments, in the step of providing the base 100, a mask material layer 110 is also formed between the target material layer 170 and the second core material layer 200.

The mask material layer 110 is used to subsequently form a second pattern transfer layer.

In some embodiments, the mask material layer 110 has a stacked structure, including a titanium nitride layer and a silicon oxide layer over the titanium nitride layer.

The second core material layer 200 is used to subsequently form second core layers and third core layers.

In some embodiments, after the second core layers are formed, the second core layers will be removed later. Thus, the material of the second core material layer 200 may be a material that is easy to remove, thereby reducing the difficulty of removing the second core layers and reducing the damage to other layers located below the second core material layer 200. Materials of the second core material layer 200 may include one or more of amorphous silicon (a-Si), polycrystalline silicon, single crystal silicon, silicon oxide, advanced patterning film (APF) material, spin on carbon (SOC), and silicon carbide. For example, the material of the second core material layer 200 may be a-Si in some cases.

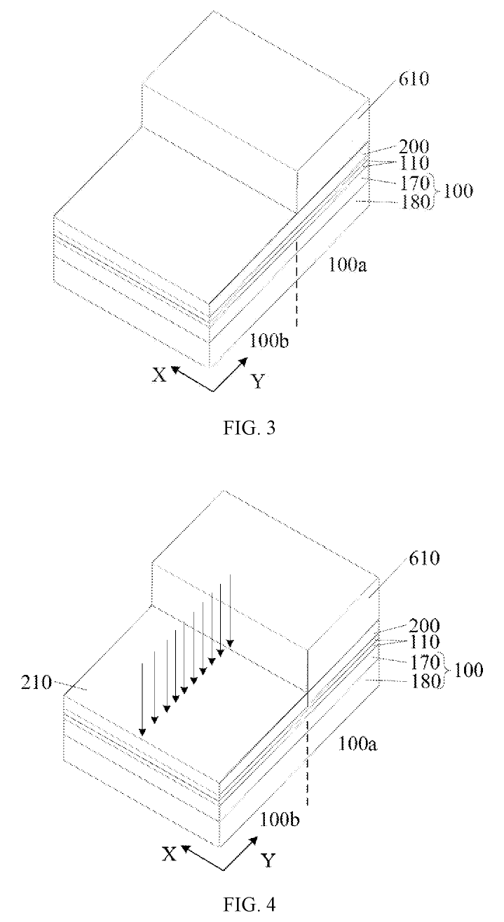

With reference to FIGS. 2 and 3, a first protective layer 610 is formed that covers the second core material layer 200 in the first area 100a.

The first protective layer 610 in the first area 100a is used to cover the first area 100a and protect the second core material layer 200 in the first area 100a from damage. The first protective layer 610 in the second area 100b is used as an implantation mask for subsequent ion implantation in the second core material layer 200 in the second area 100b.

In some embodiments, the material of the first protective layer 610 includes SOC material.

Referring to FIG. 2, the step of forming the first protective layer 610 covering the second core material layer 200 in the first area 100a includes forming a first protective material layer 600 covering the second core material layer 200.

The first protective material layer 600 is used to form the first protective layer 610.

Accordingly, in some embodiments, the first protective material layer 600 is a planarization layer, and the material of the first protective material layer 600 includes an SOC material. The SOC is formed by a spin coating process, and the process cost is relatively low. By using the SOC, it is beneficial to improve the top surface flatness of the first protective material layer 600, thereby providing a good interface for the formation of the first protective layer.

Referring to FIG. 3, the first protective material layer 600 in the second area 100b is removed, and the first protective material layer 600 in the first area 100a is retained as the first protective layer 610.

Referring to FIG. 4, a portion of the second core material layer 200 in the second area 100b is modified using the first protective layer 610 as a mask. A third core material layer 210 is formed that has an etching selectivity ratio with the remaining second core material layer 200.

The second core material layer 200 in the second area 100b is modified to obtain the third core material layer 210 having an etching selectivity ratio with the second core material layer 200. The remaining second core material layer 200 may be easily removed later. As such, in the process of removing the remaining second core material layer 200, the damage to the third core material layer 210 is reduced. The third core material layer 210 is used to prepare for patterning the target material layer 170 in the second area 100b.

In some embodiments, in the step of modifying the second core material layer 200 in the second area 100b with the first protective layer 610 as a mask, the second core material layer 200 is ion implanted with the first protective layer 610 as a mask to form the third core material layer 210 that has an etching selectivity ratio with the remaining second core material layer 200.

The ion implantation process has the characteristics of uniform large-area ion implantation, more accurate control of ion doping depth and high repeatability. The third core material layer 210 is obtained by ion implantation, which is conducive to accurately controlling the doping concentration and distribution of the third core material layer 210 and the penetration depth of the second core material layer 200. The ion distribution in the third core material layer 210 is relatively uniform.

In some embodiments, in the step of performing ion implantation in the second core material layer 200 using the first protective layer 610 as a mask, ions implanted by the ion implantation include one or more of boron, phosphorus, arsenic, boron chloride, boron dichloride, and carbon.

In some embodiments, the material of the second core material layer 200 is a-Si. By implanting one or more ions of boron, phosphorus, arsenic, boron chloride, boron dichloride, and carbon in the second core material layer 200, a-Si may be converted into a material having a higher etching selectivity with a-Si, thereby obtaining a third core material layer 210 having a higher etching selectivity with the second core material layer 200.

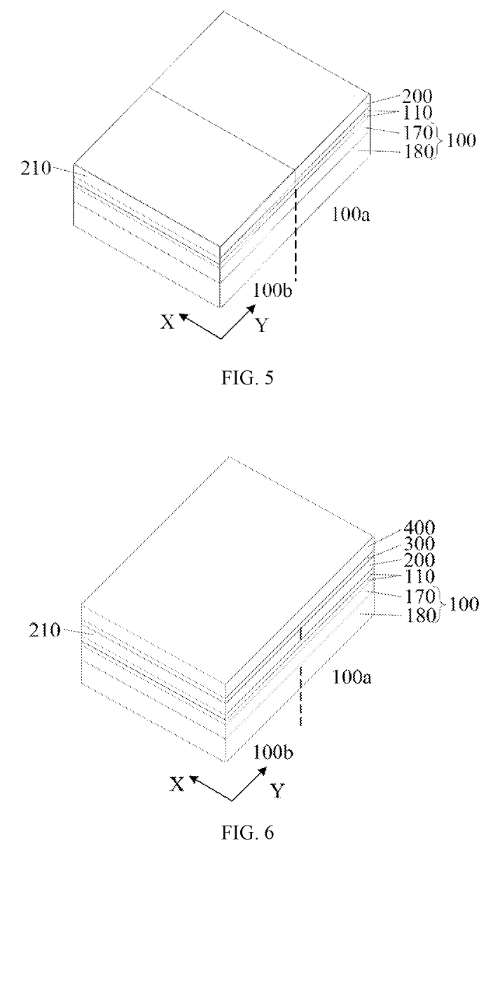

Referring to FIG. 5, the first protective layer 610 is removed.

Removing the first protective layer 610 prepares for the formation of a second protective layer.

In some embodiments, an etching process is used to remove the first protective layer 610.

In some embodiments, either an isotropic or anisotropic etching process may be used. It is only necessary to ensure the etching selectivity of the etching process. As such, the etching process has a relatively large etching selectivity between the first protective layer 610 and the second core material layer 200, and between the first protective layer 610 and the third core material layer 210. It reduces damages to the second core material layer 200 and the third core material layer 210 in the process of removing the first protective layer 610.

Referring to FIG. 6, before forming the first core material layer covering the second core material layer 200 and the third core material layer 210, the method also includes forming an etch stop layer 300 covering the first core material layer 200 and the second core material layer 200.

The etch stop layer 300 is used to subsequently form a first pattern transfer layer. The etch stop layer 300 is also used as an etch stop layer when the first core material layer is subsequently patterned, and protects the second core material layer 200 to prevent the second core material layer 200 from being damaged.

In some embodiments, the material of the etch stop layer 300 includes one or more of silicon oxide, silicon nitride, silicon oxynitride, silicon carbide, titanium, titanium oxide, titanium nitride, tantalum, tantalum oxide, tantalum nitride, boron nitride, copper nitride, aluminum nitride, and tungsten nitride. Exemplarily, the material of the etch stop layer 300 is silicon oxide.

Referring to FIG. 6, a first core material layer 400 covering the second core material layer 200 and the third core material layer 210 is formed.

The first core material layer 400 is used to form first core layers.

In the some embodiments, in the step of forming the first core material layer 400 covering the second core material layer 200 and the third core material layer 210, the first core material layer 400 covers the etch stop layer 300.

In some embodiments, after the first core layers are formed, the first core layers will be removed later. Therefore, the material of the first core material layer 400 is a material that is easy to remove, thereby reducing the difficulty of removing the first core layers and reducing the damage to other layers below the first core material layer 400. Therefore, the material of the first core material layer 400 includes one or more of a-Si, polycrystalline silicon, single crystal silicon, silicon oxide, APF material, SOC, and silicon carbide. Exemplarily, the material of the first core material layer 400 is a-Si.

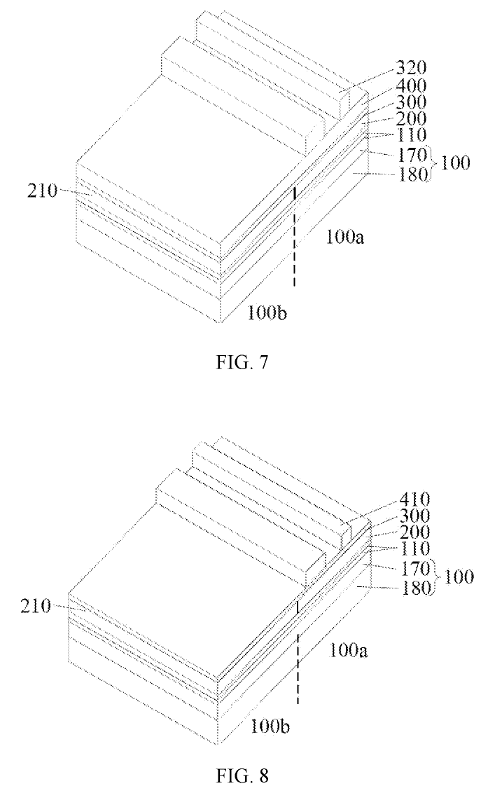

Referring to FIGS. 7 and 8, the first core material layer 400 is patterned to form separate first core layers 410 in the first area 100a. The first core layers 410 extend along a first direction (as shown in the X direction in FIG. 8) and are arranged in parallel along a second direction (as shown in the Y direction in FIG. 8), and the first direction is perpendicular to the second direction.

The first core layers 410 are used to provide support for formation of the first spacers.

In some embodiments, the first core material layer 400 is patterned by a dry etching process. Dry etching of a-Si is easier to stop on silicon oxide material used exemplarily as the first etch stop layer 300.

The dry etching process has anisotropic etching characteristics. Its longitudinal etching rate is much greater than the lateral etching rate. Therefore, by selecting dry etching process, it is beneficial to improve the accuracy of pattern transfer. At the same time, dry etching is more directional, which is beneficial to improve the sidewall morphology quality and dimensional accuracy of the first core layers 410.

Correspondingly, in some embodiments, the material of the first core layers 410 is a-Si, so that in the process of patterning the first core material layer 400, the damage to the etch stop layer 300 is reduced. After the first core material layer 400 is patterned, the etch stop layer 300 still maintains a good size and morphology accuracy. As the first core layers 410 are made of a material that is easy to remove, subsequent processes of removing the first core layers 410 have little effect on the etch stop layer 300.

In some embodiments, the size and pitch of the first core layers 410 are set according to the size and pitch of the first target structures formed in the first area 100a.

Referring to FIG. 7, the step of patterning the first core material layer 400 includes forming separate first mask layers 320 on the first core material layer 400 in the first area 100a.

The first mask layers 320 are used as an etching mask for patterning the first core material layer 400.

In some embodiments, the first mask layer 320 includes an SOC layer, a silicon-containing antireflective coating (Si-ARC) layer on the SOC, and a photoresist layer on the Si-ARC layer. The first mask layer 320 may be formed by photolithography and several etching steps.

Referring to FIG. 8, the first core material layer 400 is patterned using the first mask layers 320 to form separate first core layers 410 in the first area 100a.

In some embodiments, after forming the first core layers 410, the method also includes removing the first mask layers 320.

Removing the first mask layers 320 prepares for subsequent formation of the first spacers.

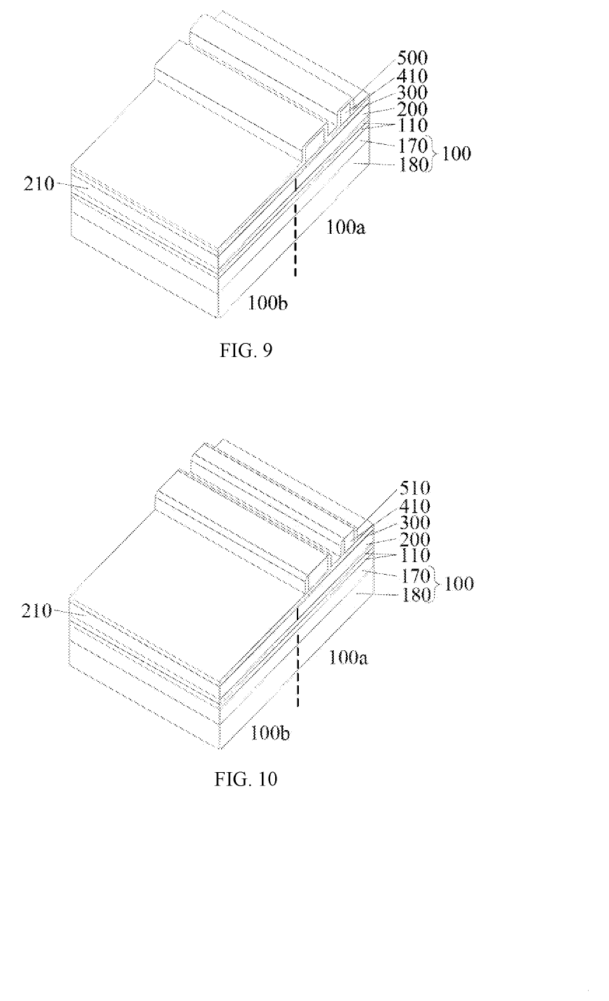

Referring to FIGS. 9 and 10, first spacers 510 covering sidewalls of the first core layers 410 are formed.

The first spacers 510 are used as an etching mask for patterning of the second core material layer 200.

In some embodiments, the material of the first spacers 510 includes one or more of titanium oxide, titanium nitride, silicon oxide, silicon nitride, silicon oxynitride, and silicon carbide.

Titanium oxide, titanium nitride, silicon oxide, silicon nitride, silicon oxynitride, and silicon carbide may form a good etching selectivity with the first core layers 410, thereby reducing the damage to the first spacers 510 in a subsequent step of removing the first core layers 410.

Referring to FIG. 9, the step of forming the first spacers 510 covering sidewalls of the first core layers 410 includes forming a first spacer material layer 500 covering sidewalls and tops of the first core layers 410 and over the second core material layer 200.

In some embodiments, the first spacer material layer 500 covers sidewalls and tops of the first core layers 410 and the top of the etch stop layer 300.

The first spacer material layer 500 is used to directly form the first spacers 510. Accordingly, the material of the first spacer material layer 500 includes one or more of titanium oxide, titanium nitride, silicon oxide, silicon nitride, silicon oxynitride, and silicon carbide.

In some embodiments, the first spacer material layer 500 covering sidewalls and tops of the first core layers 410 and the top of the etch stop layer 300 is formed by an ALD process.

The first spacer material layer 500 formed by ALD has good thickness uniformity and good step coverage, so that the first spacer material layer 500 may conformally cover the sidewalls and tops of the first core layers 410 and the top of the etch stop layer 300.

Referring to FIG. 10, the first spacer material layer 500 on the tops of the first core layers 410 and over the second core material layer 200 is removed, and the first spacer material layer 500 on the sidewalls of the first core layers 410 is retained as the first spacers 510.

In some embodiments, the first spacer material layer 500 on the tops of the first core layers 410 and the top of the etch stop layer 300 is removed.

In some embodiments, a dry etching process is used to remove the first spacer material layer 500 at the tops of the first core layers 410 and the top of the etch stop layer 300.

Dry etching process is an anisotropic etching process. By selecting dry etching process, it is beneficial to reduce the damage to the first core layers 410 and the etch stop layer 300. At the same time, dry etching is more directional, which is beneficial to improve the sidewall morphology quality and dimensional accuracy of the first spacers 510.

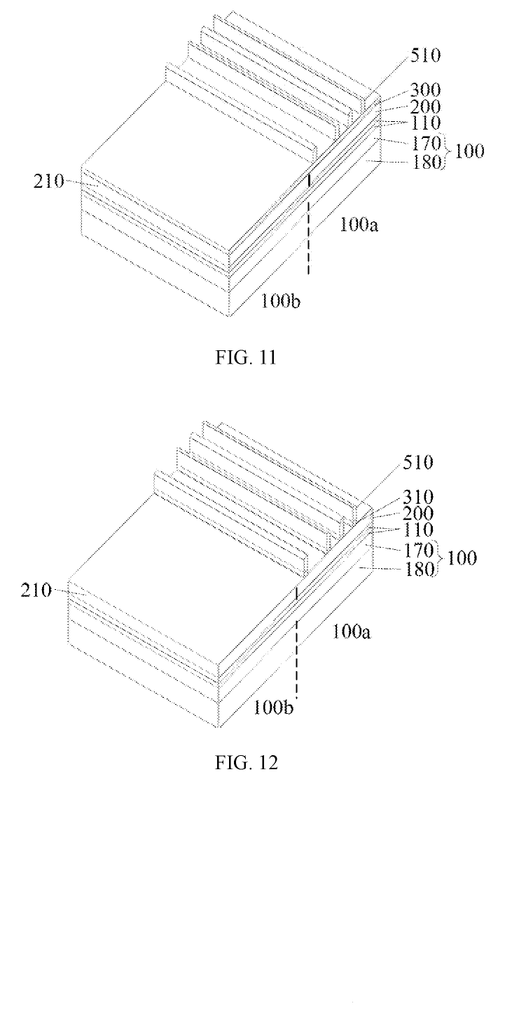

Referring to FIG. 11, the first core layers 410 are removed.

Removing the first core layers 410 prepares for patterning of the etch stop layer 300 and the second core material layer 200 with the first spacers 510 as a mask.

In some embodiments, a wet etching process is used to remove the first core layers 410.

The wet etching process has the characteristics of isotropic etching, which is conducive to clean removal of the first core layers 410. Moreover, the cost of wet etching process is relatively low, and the operation steps are simple. It may also achieve a large etching selectivity ratio, which is conducive to reducing the damage to the first spacers 510 during removal of the first core layers 410.

Referring to FIG. 12, before the second protective layer is formed on the second core material layer 200 in the second area 100b, the method also includes patterning the etch stop layer 300 with the first spacers 510 as a mask and forming first pattern transfer layers 310.

The first pattern transfer layers 310 are used as an etching mask for patterning the second core material layer 200 in the first area 100a.

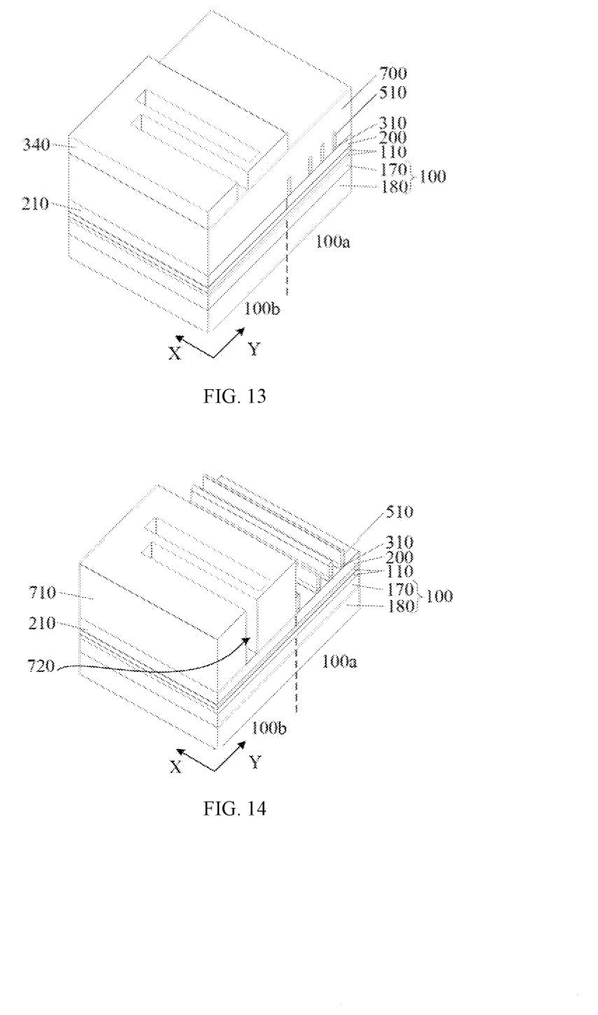

Referring to FIGS. 13 and 14, a second protective layer 710 is formed on the third core material layer 210 in the second area 100b. Separate second protective layer openings 720 extending along the first direction and arranged in parallel along the second direction are formed in the second protective layer 710.

The second protective layer 710 is used as an etching mask for patterning the third core material layer 210.

In some embodiments, the material of the second protective layer 710 includes an SOC material.

In some embodiments, in the step of forming the second protective layer 710 on the third core material layer 210 in the second area 100b, the size of the second protective layer openings 720 along the second direction is 35 nm to 200 nm, and the pitch of the second protective layer openings 720 along the second direction is 76 nm to 200 nm. The size of third core layer opening formed by patterning the third core material layer 210 is 35 nm to 200 nm along the second direction.

Referring to FIG. 13, the step of forming the second protective layer 710 on the third core material layer 210 in the second area 100b includes forming a second protective material layer 700 covering the second core material layer 200, the third core material layer 210, and the first spacers 510.

The second protective material layer 700 is used to form the second protective layer 710.

In some embodiments, the second protective material layer 700 is a planarization layer, and the material of the second protective material layer 700 includes an SOC material. SOC is formed by a spin-coating process, and the process cost is low. Moreover, the use of SOC is conducive to improving the flatness of the top surface of the second protective material layer 700, thereby providing a good interface for formation of the second protective layer 710.

In some embodiments, the second protective material layer 700 also covers sidewalls of the first pattern transfer layers 310 in the first area 100a.

In some embodiments, a second mask layer 340 is also formed on the second protective material layer 700. The second mask layer 340 is located on the first protective material layer 600 in the second area 100b, and separate mask openings extending along the first direction and arranged in parallel along the second direction are formed.

The second mask layer 340 is used to pattern the second protective material layer 700.

In some embodiments, the second mask layer 340 includes Si-ARC and a photoresist layer located on the Si-ARC.

Referring to FIG. 14, the second protective material layer 700 is patterned. The second protective material layer 700 in the first area 100a is removed. Portions of the second protective material layer 700 in the second area 100b that extend along the first direction and the second direction are removed, and remaining portions of the second protective material layer 700 in the second area 100b are retained as the second protective layer 710.

In some embodiments, the second mask layer 340 is used as an etching mask to pattern the second protective material layer 700.

In some embodiments, after patterning the second protective material layer 700, the method further includes removing the second mask layer 340.

In some embodiments, a photomask and related photolithography and etching processes are used to pattern the second mask layer 340 in the first area 100a and the second area 100b. The second mask layer 340 is used to pattern the second protective material layer 700 to form the second protective layer 710. Then the second protective layer 710 in the second area 100b and the first spacers 510 in the first area are used as a mask to pattern the second core material layer 200 and the third core material layer 210, forming second core layers 220 and third core layers 230. Since the process of forming the second mask layer 340 by using a photomask is highly flexible, the patterns are diverse, and the design is relatively free within the range allowed by a single photolithography. That is, the size and pitch of the second protective layer openings 720 in the second protective layer 710 are relatively not limited, as long as they meet the single DUV lithography limit and the pitch is greater than about 76 nm. Accordingly, the size and pitch design of trenches surrounded by the second spacer material layer supported by sidewalls of the second core layers 220 and the third core layers 230 are relatively not limited. Therefore, the second target structures with a larger pitch may be obtained in the second area 100b, and the freedom of pattern design is improved.

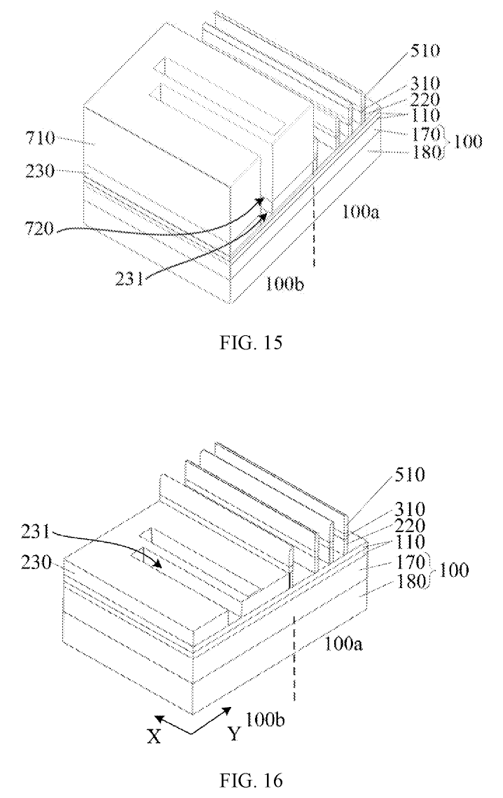

Referring to FIG. 15, the second core material layer 200 and the third core material layer 210 are patterned using the first spacers 510 and the second protective layer 710 as a mask, forming the second core layers 220 corresponding to the second core material layer 200, the third core layers 230 corresponding to the third core material layer 210, and third core layer openings 231 corresponding to the second protective layer openings 720 in the third core layers 230.

The second core layers 220 and the third core layers 230 are used to provide support for formation of the second spacers.

The second core layers 220 are patterned from the second core material layer 200 in the first area 100a, and the third core layers 230 are patterned from the third core material layer 210 in the second area 100b. The etching selectivity between the second core material layer 200 and the third core material layer 210 due to the modification treatment does not disappear through a patterning process. In other words, the second core layers 220 and the third core layers 230 still retain a high etching selectivity. For example, during an etching process with potassium hydroxide (KOH) or standard clean 1 (SC1) solution, the second core layers 220 may be removed at a faster etching rate, while there is almost no loss to the third core layers 230.

After the second core layers 220 are removed, the third core layers 230 are used as a partial etching mask for patterning the target material layer 170 in the second area 100b, and are also used to provide support for formation of the second spacers.

In some embodiments, the material of the second core layers 220 is a-Si, and the material of the third core layer 230 is a-Si doped with boron, phosphorus, or arsenic.

In some embodiments, in the step of patterning the second core material layer 200 and the third core material layer 210 using the first spacers 510 and the second protective layer 710 as a mask, the second core material layer 200 in the first area 100a is patterned using the first pattern transfer layers 310 as a mask and separate second core layers 220 are formed in the first area 100a.

The second core material layer 200 in the first area 100a is patterned using the first pattern transfer layers 310 as a mask and separate second core layers 220 are formed in the first area 100a, which is conducive to improving the pattern transfer accuracy and pattern size accuracy of the second core layers 220.

Optionally, the second core layers 220 in the first area 100a are transferred from the first spacers 510, and the pitch of the first spacers 510 has been halved based on the pitch of the first mask layers 320. This is also an SADP process, which has halved the single DUV lithography etching limit of about 80 nm to about 40 nm. This is to prepare for the subsequent formation of the second spacers on sidewalls of the second core layers 220 to achieve another halving of the second spacer pitch compared to the first spacers 510. This is also the characteristic of SAQP and the reason why SAQP may form a pattern with a pitch of about 24 nm.

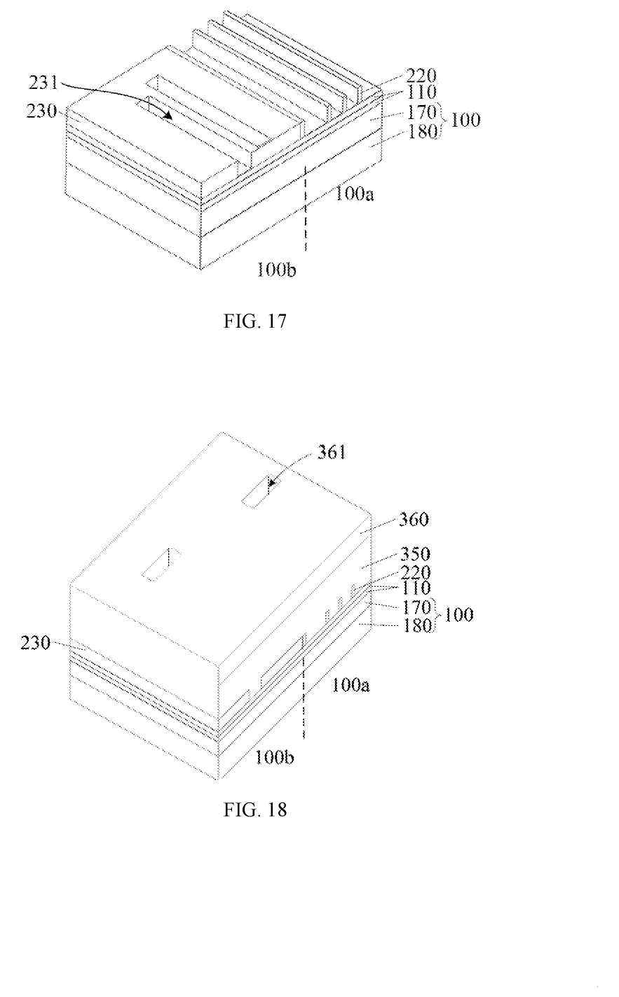

Referring to FIGS. 16 and 17, the first spacers 510 and the second protective layer 710 are removed.

Removing the first spacers 510 and the second protective layer 710 prepares for subsequent removal of the second core layers 220.

Referring to FIG. 16, the second protective layer 710 is removed by an etching process.

In some embodiments, either an isotropic or anisotropic etching process may be used. It is only necessary to ensure the etching selectivity of the etching process so that the etching process has a relatively large etching selectivity for the second protective layer 710 and the second core layers 220, as well as for the second protective layer 710 and the third core layers 230, thereby reducing the damage to the second core layers 220 and the third core layers 230 during the removal of the second protective layer 710.

Referring to FIG. 17, removal of the first spacers 510 prepares for formation of the second spacers.

In some embodiments, after forming the second core layers 220 and the third core layers 230, the method also includes removing the first pattern transfer layers 310.

Removing the first pattern transfer layers 310 prepares for subsequent formation of the second spacers.

In some embodiments, a wet etching process is used to remove the first spacers 510 and the first pattern transfer layers 310.

The wet etching process has characteristics of isotropic etching, which is conducive to removing the first spacers 510 and the first pattern transfer layers 310. Moreover, the cost of the wet etching process is relatively low, and the operation steps are simple. It may also achieve a large etching selectivity ratio, which is conducive to reducing the damage to the second core layers 220 during the removal of the first spacers 510 and the first pattern transfer layers 310.

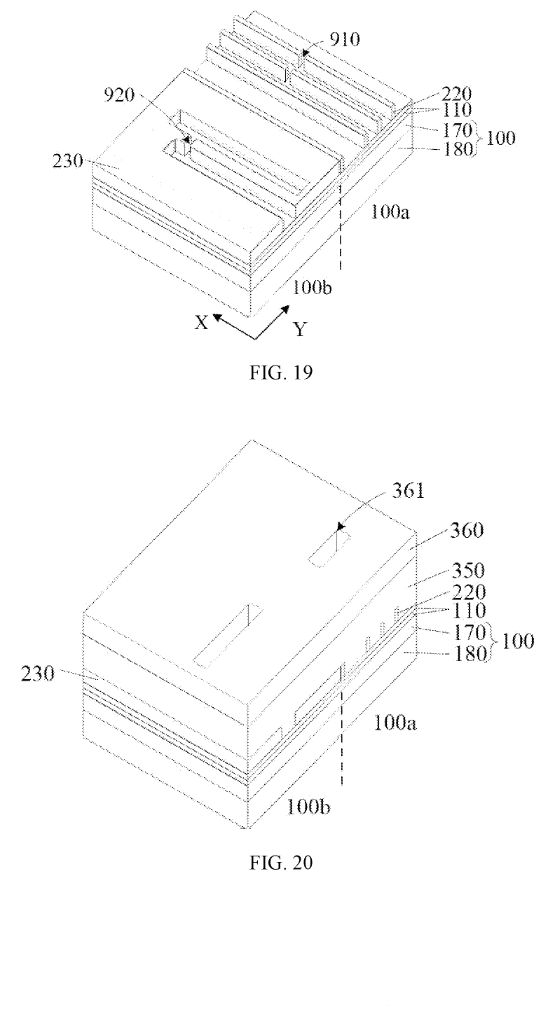

Referring to FIGS. 18 and 19, after removing the first spacers 510 and the second protective layer 710, and before forming the second spacers covering sidewalls of the second core layers 220 and the third core layers 230, the method also includes patterning the second core layers 220 in the first area 100a and part of the third core layers 230 in the second area 100b, forming first separation openings 910 that cut off part of the second core layers 220 in the first direction, and forming second separation openings 920 that cut off the third core layers 230 in the second area 100b in the first direction.

The first separation openings 910 are used to form first separation structures, and the second separation openings 920 are used to form second separation structures.

In some embodiments, the step of patterning the second core layers 220 in the first area 100a and the third core layers 230 in the second area 100b, forming the first separation openings 910 that cut off the second core layers 220 in the first area 100a in the first direction, and forming the second separation openings 920 that cut off the third core layers 230 in the second area 100b in the first direction includes the following: Referring to FIG. 18, forming a fourth protective layer 350 covering the second core layers 220 and the third core layers 230, forming a fourth mask layer 360 on the fourth protective layer 350, and forming third mask layer openings 361 that cross the second core layers 220 and the third core layers 230 along the second direction in the fourth mask layer 360; and referring to FIG. 19, patterning the second core layers 220 and the third core layers 230 through the fourth protective layer 350 and the third mask layer openings 361, forming the first separation openings 910 that cut off the second core layers 220 in first area 100a in the first direction, and forming the second separation openings 920 that cut off the third core layers 230 in the second area 100b in the first direction.

In some embodiments, the fourth protective layer 350 is a planarization layer, and the material of the fourth protective layer 350 includes an SOC material. SOC is formed by a spin coating process, and the process cost is relatively low. Moreover, using SOC is beneficial to improve the flatness of the top surface of the fourth protective layer 350, thereby providing a good interface for formation of the fourth mask layer 360.

The fourth mask layer 360 is used to pattern the second core layers 220 and the third core layers 230 through the fourth protective layer 350.

In some embodiments, the fourth mask layer 360 includes a Si-ARC and a photoresist layer arranged on the Si-ARC.

Referring to FIG. 19, after forming the first separation openings 910 that cut off the second core layers 220 in the first area 100a in the first direction and the second separation openings 920 that cut off the third core layers 230 in the second area 100b in the first direction, the method also includes removing the fourth protective layer 350 and the fourth mask layer 360.

Optionally, based on actual process requirements, the steps related to FIGS. 18 and 19 may be repeated to form multiple first separation openings 910 and second separation openings 920 at target positions.

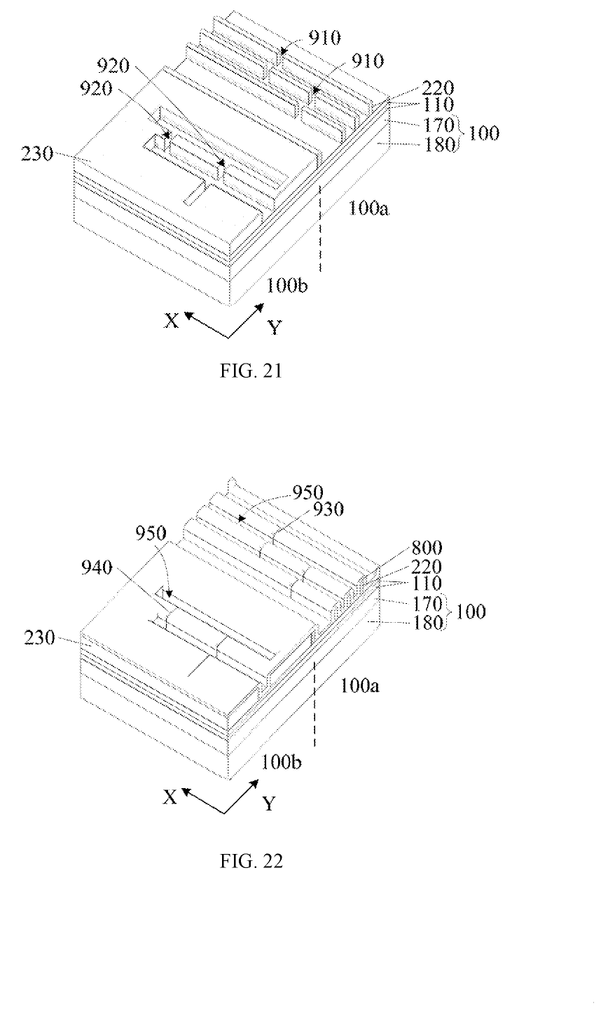

As an example, the steps of forming the first separation openings 910 and the second separation openings 920 may be performed twice, as shown in FIGS. 20 and 21. Exemplary steps include forming the fourth protective layer 350 covering the second core layers 220 and the third core layers 230, forming the fourth mask layer 360 on the fourth protective layer 350, forming the third mask layer openings 361 that are in the fourth mask layer 360 and cross part of the second core layers 220 and the third core layers 230 along the second direction, patterning the second core layers 220 and the third core layers 230 through the fourth protective layer 350 and the third mask layer openings 361, forming the first separation openings 910 that cut off or separate the second core layers 220 in the first area 100a along the first direction, and forming the second separation openings 920 that cut off or separate the third core layers 230 in the second area 100b along the first direction.

Referring to FIGS. 22 to 28, second spacers 810 covering sidewalls of the second core layers 220 and the third core layers 230 are formed.

The second spacers 810 are used as a partial etching mask for patterning the target material layer 170 in the first area 100a and the second area 100b.

In some embodiments, the material of the second spacers 810 includes one or more of titanium oxide, titanium nitride, silicon oxide, silicon nitride, silicon oxynitride, and silicon carbide.

Titanium oxide, titanium nitride, silicon oxide, silicon nitride, silicon oxynitride, and silicon carbide may form a good etching selectivity with the second core layers 220 and the third core layers 230, thereby reducing the damage to the second spacers 810 in subsequent steps of removing the second core layers 220.

In some embodiments, in the step of forming the second spacers 810 covering sidewalls of the second core layers 220 and the third core layers 230, the second spacers 810 also cover sidewalls of the first separation openings 910 and the second separation openings 920. The double thickness of the second spacer 810 is smaller than the size of the first separation opening 910 and the second separation opening 920 along the first direction. Thus, second spacers 810 on opposite sidewalls of the first separation opening 910 contact each other to form a first separation structure 930. Second spacers 810 on opposite sidewalls of the second separation opening 920 contact each other to form a second separation structure 940.

The first separation structures 930 and the second separation structures 940 are used to transfer a pattern to the target material layer 170. As such, the cut or separation of the first target structures and the cut or separation of the second target structures may be directly formed in the target material layer 170. After the target material layer 170 is subsequently patterned, some first target structures to be cut and some second target structures to be cut may be directly cut off while the first target structures and the second target structures are formed in the target material layer 170.

Referring to FIG. 22, the step of forming the second spacers 810 covering sidewalls of the second core layers 220 and the third core layers 230 includes forming a second spacer material layer 800 covering sidewalls and tops of the second core layers 220 and the third core layers 230 and the top of the base 100.

The second spacer material layer 800 is used to directly form the second spacers 810. The material of the second spacer material layer 800 includes one or more of titanium oxide, titanium nitride, silicon oxide, silicon nitride, silicon oxynitride, and silicon carbide.

In some embodiments, ALD is used to form the second spacer material layer 800 covering sidewalls and tops of the second core layers 220 and the third core layers 230 and the top of the base 100.

The second spacer material layer 800 formed by ALD has good thickness uniformity and good step coverage, so that the second spacer material layer 800 may conformally cover sidewalls and tops of the second core layers 220 and the third core layers 230, as well as the top of the base 100.

In some embodiments, in the step of forming the second spacer material layer 800 covering sidewalls and tops of the second core layers 220 and the third core layers 230 and the top of the base 100, the second spacer material layer 800 also fills the first separation openings 910 and the second separation openings 920.

Portions of the second spacer material layer 800 that covers sidewalls of the second core layers 220, the third core layers 230, and fourth core layers 240 are used as the second spacers 810. Portions of the second spacer material layer 800 that fill the first separation openings 910 are used as the first separation structures 930. Portions of the second spacer material layer 800 that fill the second separation openings 920 are used as the second separation structures 940.

In some embodiments, when the second spacer material layer 800 is formed to cover sidewalls and tops of the second core layers 220 and the third core layers 230 and the top of the base 100, portions of the second spacer material layer 800 on the opposite sidewalls form trenches 950.

Optionally, the first separation structures 930 only cut some first target structures corresponding to (directly below) the second core layers 220 in the first area 100a, but do not cut trenches 950 surrounded by the second spacers 810 of the second core layers 220 and some first target structures corresponding to the trenches 950. This is also a special feature of the self-aligned block (SAB) technology mentioned in the background technology. Similarly, the second separation structures 940 only cut the second target structures corresponding to the third core layers 230 in the second area 100b, but do not cut second target structures corresponding to the trenches 950 surrounded by the second spacer material layer 800 on sidewalls of the third core layers 230.

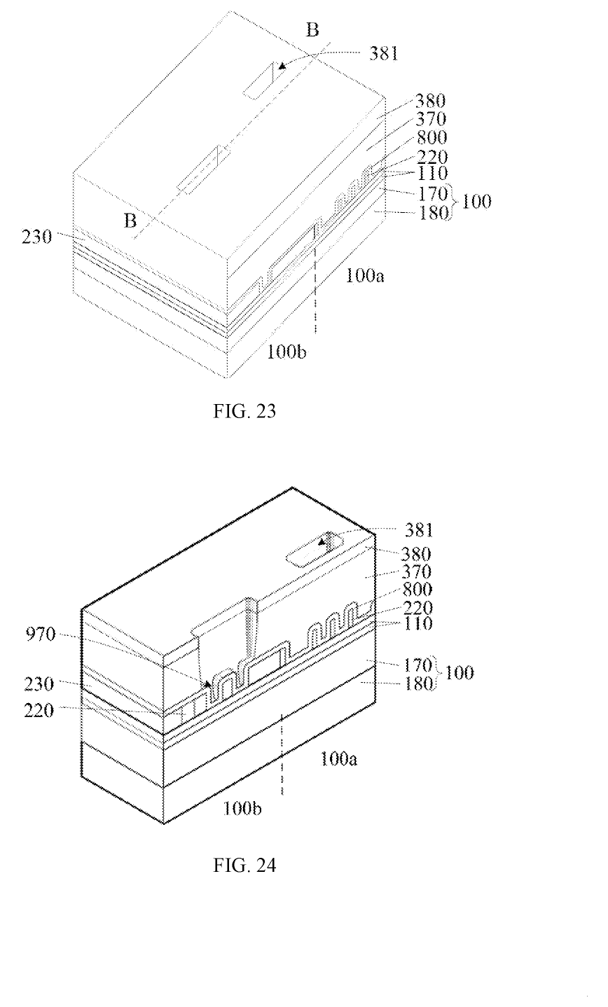

Referring to FIGS. 23-27, after forming the second spacers 810 covering sidewalls of the second core layers 220 and the third core layers 230, and before removing the second spacer material layer 800 on the tops of the second core layers 220, the third core layers 230, and the base 100, the method also includes forming third separation structures 960 extending along the second direction and contacting the second spacers 810 in the trenches 950 in the first area 100a and the second area 100b. The third separation structures 960 cut off the trenches 950 in the first direction.

The third separation structures 960 are used to transfer a pattern to the target material layer 170, so that cuts or separation are made for first target structures and second target structures corresponding to the trenches 950 in the first area 100a and the second area 100b in the target material layer 170. After the target material layer 170 is patterned, when the first target structures and second target structures are formed, some first target structures to be cut are cut off and some second target structures to be cut are cut off.

The third separation structures 960 only cut (or separate) first target structures corresponding to (directly below) the trenches 950 in the first area 100a, and do not cut first target structures corresponding to the second core layers 220. This is also a special feature of the SAB technology mentioned in the background technology. Similarly, the third separation structures 960 only cut some second target structures corresponding to the trenches 950 in the second area 100b, but do not cut second target structures corresponding to the third core layers 230 in the second area 100b.

Optionally, in the first area 100a, the separation (or cut) transferred from the third separation structures 960 to the target material layer 170 and the separation transferred from the first separation structures 930 to the target material layer 170 are separation of adjacent first target structures. In the second area 100b, the separation transferred from the third separation structures 960 to the target material layer 170 and the separation transferred from the second separation structures 940 to the target material layer 170 are separation of adjacent second target structures. Thus, the first separation structures 930, the second separation structures 940, and the third separation structures 960 may be pre-formed. Adjacent first target structures or adjacent second target structures are separated in the target material layer 170 by the pre-formed first, second, and third separation structures. It provides a better method for forming separation with a smaller pitch.

Referring to FIGS. 23 and 24, FIG. 24 is a cross-sectional view of FIG. 23 along the BB direction. In some embodiments, the step of forming third separation structures 960 that extend along the second direction and contact the second spacers 810 in the trenches 950 in the first area 100a and the second area 100b includes the following: Forming a fifth protective layer 370 covering the second spacer material layer 800 and filling the trenches 950, forming a fifth mask layer 380 on the fifth protective layer 370, forming fifth mask layer openings 381 across the trenches 950 along the second direction in the fifth mask layer 380, patterning the fifth protective layer 370 through the fifth mask layer openings 381, removing the fifth protective layer 370 corresponding to positions of the fifth mask layer openings 381 in the trench 950, and forming third separation openings 970.

In some embodiments, the fifth protective layer 370 is a planarization layer, and the material of the fifth protective layer 370 includes a SOC material. The SOC is formed by a spin coating process, and the process cost is relatively low. Moreover, by adopting SOC, it is beneficial to improve the top surface flatness of the fifth protective layer 370, thereby providing a good interface for formation of the fifth mask layer 380.

The fifth mask layer 380 is used to pattern the fifth protective layer 370 to form the third separation openings 970.

In some embodiments, the fifth mask layer 380 includes a Si-ARC and a photoresist layer on the Si-ARC.

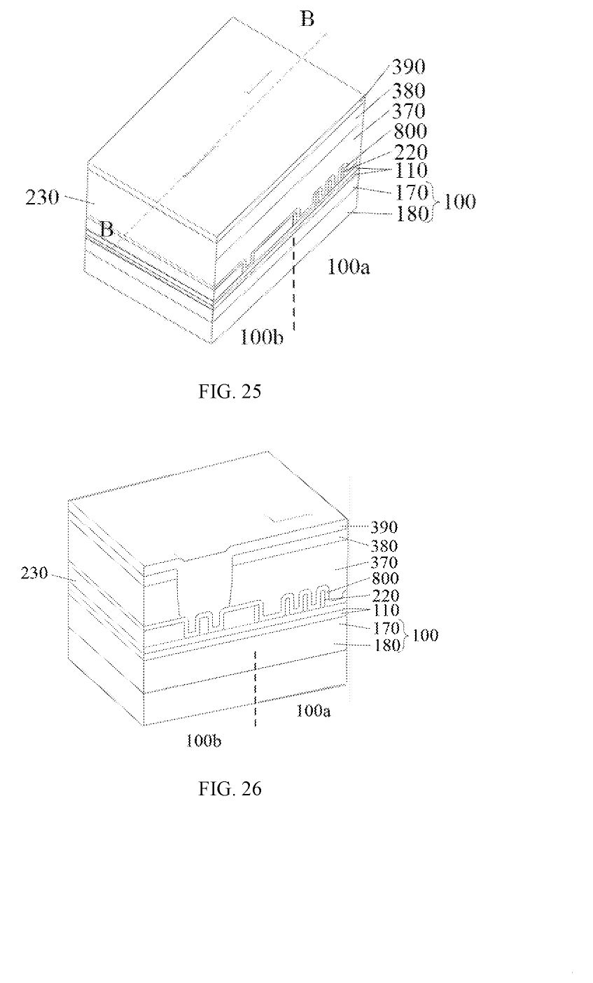

Referring to FIGS. 25 and 26, FIG. 26 is a cross-sectional view of FIG. 25 along the BB direction. A separation material layer 390 filling the third separation openings 970 is formed.

The separation material layer 390 is used to form the third separation structures 960.

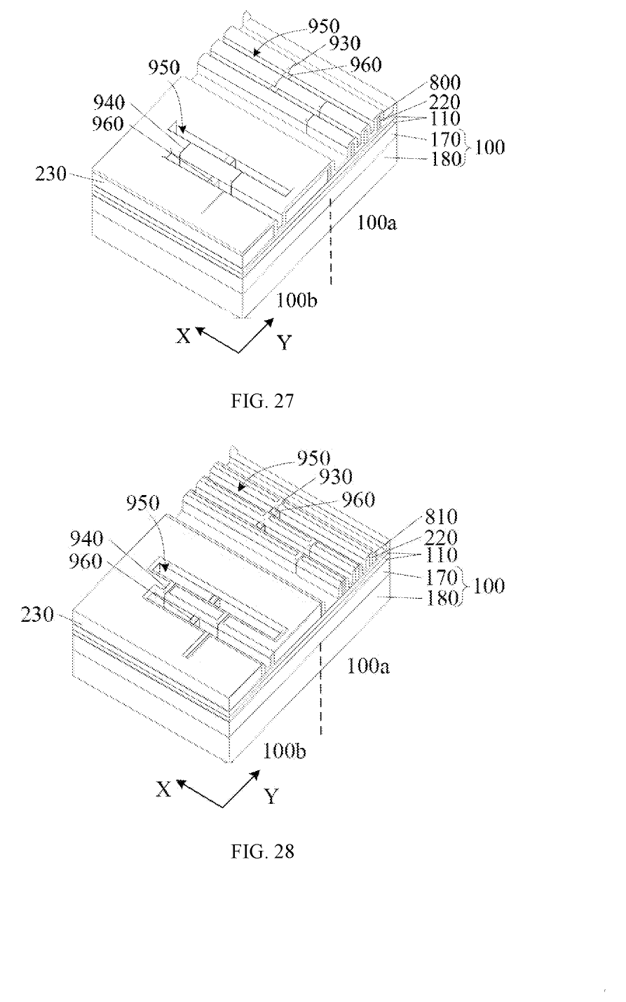

Referring to FIG. 27, after forming the separation material layer 390 filling the third separation openings 970, the method also includes removing the fifth protective layer 370, the fifth mask layer 380, and part of the separation material layer 390 higher than the second spacer material layer 800.

Referring to FIG. 28, portions of the second spacer material layer 800 on tops of the second core layers 220, the third core layers 230, and the base 100 are removed. Portions of the second spacer material layer 800 on sidewalls of the second core layers 220 and the third core layers 230 are retained as the second spacers 810. Portions of the second spacer material layer 800 below the third separation material layer 390 in the trenches 950 surrounded by the second spacer material layer 800 are retained to form the third separation structures 960.

In some embodiments, a dry etching process is used to remove the second spacer material layer 800 on tops of the second core layers 220, the third core layers 230, and the base 100.

The dry etching process is an anisotropic etching process. Therefore, by selecting dry etch, it is beneficial to reduce the damage to the second core layers 220 and the third core layers 230. At the same time, dry etch is more directional, which is beneficial to improve the sidewall morphology quality and dimensional accuracy of the second spacers 810.

In some embodiments, the second spacer material layer 800 on tops of the second core layers 220, the third core layers 230, and the base 100 is removed to expose the second core layers 220 and the third core layers 230.

In some embodiments, in the step of removing the second spacer material layer 800 on tops of the second core layers 220, the third core layers 230, and the base 100, portions of the separation material layer 390 higher than the tops of the second core layers 220 and the third core layers 230 are also removed. Portions of the separation material layer 390 in the third separation openings 970 are retained as the third separation structures 960 for subsequent pattern transfer to the target material layer 170.

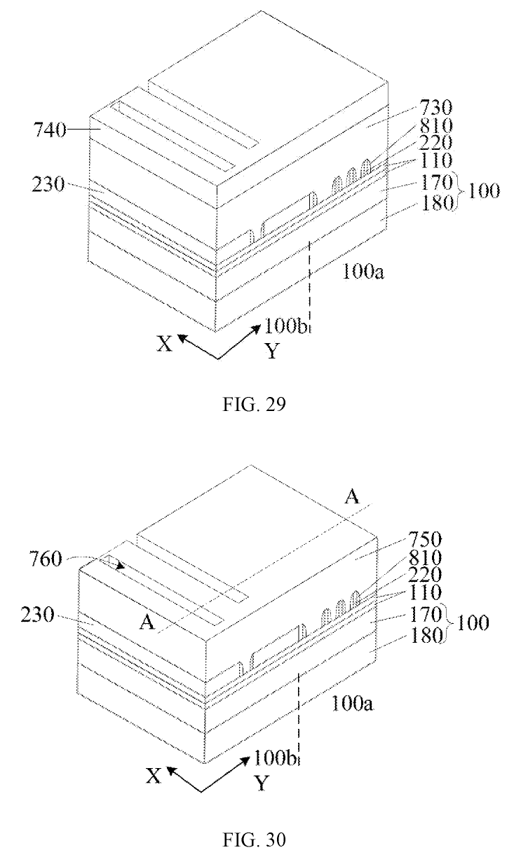

Referring to FIGS. 29 and 30, a third protective layer 750 is formed to cover the second core layers 220, the third core layers 230, and the second spacers 810. In the third protective layer 750, separate third protective layer openings 760 are formed that extend along the first direction and are arranged in parallel along the second direction. The third protective layer 750 fills the third core layer openings 231. The third protective layer openings 760 expose the third core layers 230.

The third protective layer 750 is used as an etching mask for patterning of the third core layers 230.

In some embodiments, the third protective layer 750 is patterned from a planarization layer. The material of the third protective layer 750 includes SOC material or SOC and a portion of the third mask layer 740 that remains. Whether the third mask layer 740 remains is related to a process selection and does not affect the subsequent steps. SOC is formed by a spin coating process, and the process cost is low. Moreover, the use of SOC is conducive to improving the flatness of the top surface of the planarization layer, thereby providing a good interface for the formation of the third protective layer 750.

In some embodiments, in the step of forming the third protective layer 750 covering the second core layers 220, the third core layers 230, and the second spacers 810, the size of the third protective layer openings 760 along the second direction is 35 nm to 200 nm, and the pitch along the second direction is 76 nm to 200 nm. When the third core layers 230 are subsequently patterned, the size of the removed portions of the third core layers 230 along the second direction is 35 nm to 200 nm, and the pitch is 76 nm to 200 nm.

Referring to FIG. 29, the step of forming the third protective layer 750 covering the second core layers 220, the third core layers 230, and the second spacers 810 includes forming a third protective material layer 730 covering the second core layers 220, the third core layers 230, and the second spacers 810.

In some embodiments, a third mask layer 740 is formed on the third protective material layer 730, and separate mask openings extending along the first direction and arranged in parallel along the second direction are formed in the third mask layer 740.

The third mask layer 740 is used to pattern the third protective material layer 730.

In some embodiments, the third mask layer 740 includes a Si-ARC and a photoresist layer on the Si-ARC.

Referring to FIG. 30, the third protective material layer 730 is patterned. Portions of the third protective material layer 730 that extend in the first direction and the second direction in the second area 100b are removed, and the remaining portions of the third protective material layer 730 are retained as the third protective layer 750.

In some embodiments, the third protective material layer 730 is patterned with the third mask layer 740 as an etching mask.

In some embodiments, after the third protective material layer 730 is patterned, the method also includes removing the third mask layer 740.

In some embodiments, a photomask and a photolithography process are used to pattern the third mask layer 740 in the second area 100b. The third mask layer 740 is used to pattern the third protective material layer 730 to form the third protective layer 750. Then, the third protective layer 750 is used as a mask to pattern the third core layers 230. The process flexibility of forming the third protective layer 750 is high, and the width and pitch of the third protective layer 750 are easy to adjust. It makes the width and pitch of the remaining portions of the third core layers 230 in the second area 100b easy to adjust. The second target structures with a larger pitch may be obtained in the second area 100b, and the design freedom of patterning is improved.

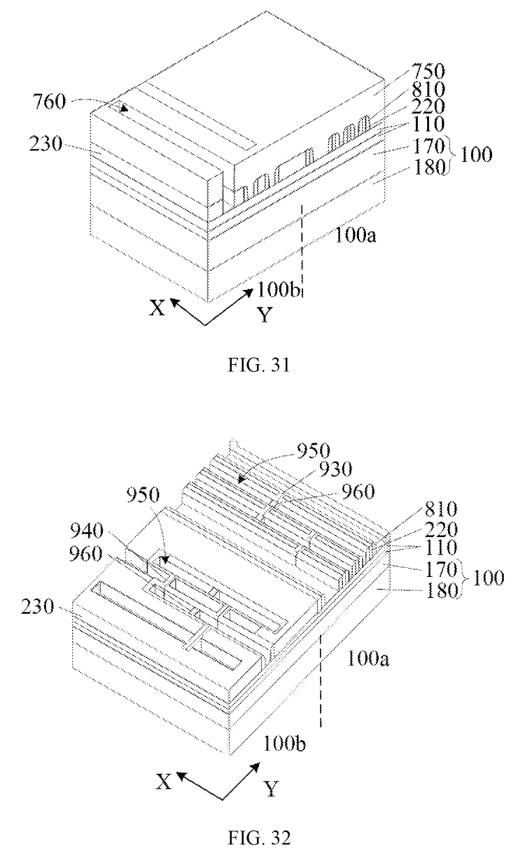

Referring to FIG. 31, the third core layers 230 are patterned with the third protective layer 750 as a mask. FIG. 31 is a view of FIG. 30 along the AA direction.

The third core layers 230 are patterned with the third protective layer 750 as a mask. The patterned third core layers 230 are subsequently used to transfer a pattern to the target material layer.

In some embodiments, when the third core layers 230 are patterned, the size of removed portions of the third core layers 230 along the second direction is 35 nm to 200 nm, and the pitch is 76 nm to 200 nm. As such, the size of the first target structures formed through pattern transfer in the target material layer 170 along the second direction is 35 nm to 200 nm, and the pitch is 76 nm to 200 nm.

Referring to FIG. 32, the third protective layer 750 is removed.

Removal of the third protective layer 750 prepares for subsequent pattern transfer.

In some embodiments, the third protective layer 750 is removed by an etching process.

In some embodiments, either an isotropic or anisotropic etching process may be used. It is only necessary to ensure the etching selectivity of the etching process. The etching process has a relatively large etching selectivity between the third protective layer 750 and the second spacers 810 and between the third protective layer 750 and the third core layers 230. The damage to the second spacers 810 and the third core layers 230 is reduced during removal of the third protective layer 750.

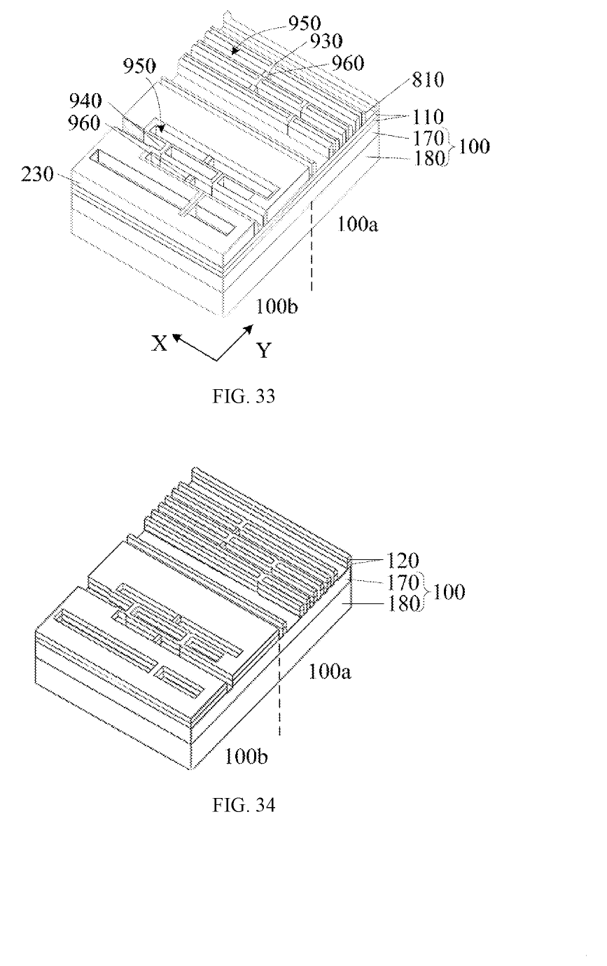

Referring to FIG. 33, the second core layers 220 are removed.

Removing the second core layers 220 prepares for patterning of the target material layer 170 in the first area 100a and the second area 100b using the second spacers 810 and the third core layers 230 as a mask.

In some embodiments, a wet etching process is used to remove the second core layers 220.

The wet etching process has the characteristics of isotropic etching, which is conducive to the clean removal of the second core layers 220. Moreover, the cost of the wet etching process is relatively low, and the operation steps are simple. It may also achieve a large etching selectivity ratio, which is conducive to reducing the damage to the second spacers 810 during the removal of the second core layers 220.

In some embodiments, in the step of removing the second core layers 220 by a wet etching process, an etching solution of the wet etching process includes one or more of KOH solution, 2,4,5-trihydroxymethamphetamine (THMA) solution, and SC1 solution.

In some embodiments, the second core layers 220 contain an undoped silicon material, and the third core layers 230 contain a doped silicon material. KOH solution or THMA solution may have a higher etching rate for undoped silicon and almost no etching rate for doped (especially B ion doped) silicon. Therefore, using KOH or THMA as an etching solution may reduce damage to the third core layers 230 while removing the second core layers 220 cleanly. In addition, alkaline solutions such as KOH solution, SC1 solution, and THMA solution have almost no etching rate on the third separation structures 960 and the second spacers 810 formed from the separation material layer 390. This makes processes of removing the second core layers 220 almost have no impact on other components in the entire pattern transfer process.

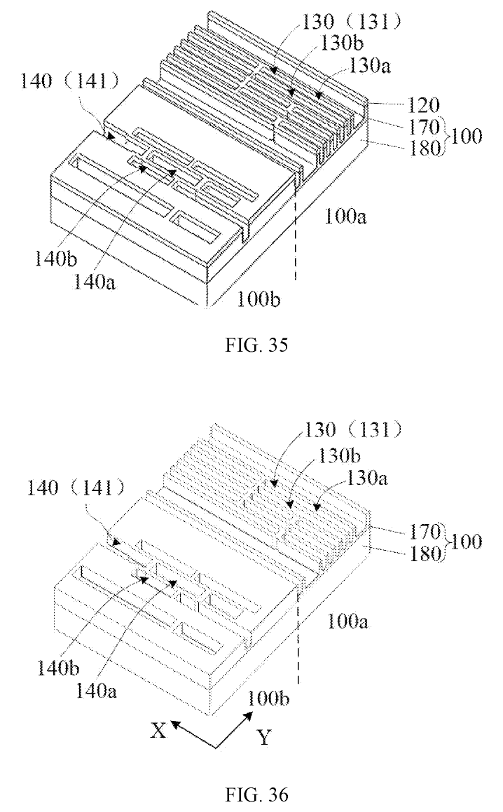

Referring to FIGS. 34 and 35, the second spacers 810 and the third core layers 230 are used as a mask to pattern the target material layer 170. The first target structures 131 in the first area 100a and the second target structures 141 in the second area 100b are formed.

In some embodiments, the second spacers 810, the third core layers 230, the first separation structures 930, the second separation structures 940, and the third separation structures 960 are used as a mask to pattern the target material layer 170, forming the first target structures 131 in the first area 100a and the second target structures 141 in the second area 100b.

In some embodiments, for the first area 100a, the first spacers 510 are formed to cover sidewalls of the first core layers 410. After the first spacers 510 are formed, the first core layers 410 are removed. The second core material layer 200 in the first area 100a is patterned with the first spacers 510 as a mask. Separate second core layers 220 are formed in the first area 100a. The second spacers 810 are formed to cover sidewalls of the second core layers 220. The target material layer 170 is patterned with the second spacers 810 as a mask. SAQP is used in the above processes. The SAQP process may form the first target structures 131 with a smaller pitch. For the second area 100b, the second core material layer 200 in the second area 100b is modified to transform the second core material layer 200 into the third core material layer 210 having an etching selectivity ratio with the second core material layer 200. The third core material layer 210 in the second area 100b is patterned using the second protective layer 710 to form the third core layers 230. The second spacers 810 covering sidewalls of the third core layers 230 are formed. The third core layers 230 are then patterned with the third protective layer 750. After the third core layers 230 are patterned, the target material layer 170 is patterned with the second spacers 810 and the third core layers 230 as a mask. The second target structures 141 with a larger pitch are formed by using the SALELE process. The present disclosure may better integrate the SAQP process and the SALELE process over the same base 100. It is possible to make the first target structures 131 with a smaller pitch and the second target structures 141 with a larger pitch on one base, which is conducive to meeting more semiconductor process requirements through process integration and improving the design freedom in patterning processes.

In some embodiments, the second spacers 810 and the third core layers 230 are used as a mask to pattern the target material layer 170. In the step of forming the first target structures 131 in the first area 100a and the second target structures 141 in the second area 100b, the first separation structures 930 and the second separation structures 940 are also used for masking to pattern the target material layer 170. Portions of the target material layer 170 corresponding to the first separation structures 930 are obtained that cut or separate the first target structures 131 in the first direction. Portions of the target material layer 170 corresponding to the second separation structures 940 are obtained that cut or separate the second target structures 141 in the first direction.

In some embodiments, the second spacers 810 and the third core layers 230 are used for masking to pattern the target material layer 170. In the step of forming the first target structures 131 in the first area 100a and the second target structures 141 in the second area 100b, the third separation structures 960 are also used for masking to pattern the target material layer 170. Portions of the target material layer 170 corresponding to the third separation structures 960 are obtained that cut or separate the first target structures 131 and the second target structures 141 in the first direction.

In some embodiments, in the step of patterning the target material layer 170 with the second spacers 810 and the third core layers 230 as a mask, a dielectric layer is patterned with the second spacers 810 and the third core layers 230 as the mask. First trenches 130 and second trenches 140 are formed in the dielectric layer.

The first trenches 130 provide space for formation of first metal lines. The second trenches 140 provide space for formation of second metal lines.

The first trenches 130 may be divided into A-type first trenches 130a and B-type first trenches 130b that are spaced apart from each other. The A-type first trench 130a is the first trench 130 corresponding to the second core layer 240 in the first area 100a, and the B-type first trench 130b is the first trench 130 corresponding to the trench 950 surrounded by the second spacer material layer 800 on the second core layers 220 in the first area 100a.

The second trenches 140 may also be divided into an A-type second trench 140a and a B-type second trench 140b. The A-type second trench 140a is the second trench 140 corresponding to the third core layers 220 corresponding to the third protective layer opening 760, and the B-type second trench 140b is the second trench 140 corresponding to the trench 950 surrounded by the second spacer material layer 800 on sidewalls of the third core layers 230.

In some embodiments, the dielectric layer corresponding to the first separation structure 930 separates the A-type first trench 130a in the first direction. The dielectric layer corresponding to the second separation structure 940 separates the A-type second trench 140a in the first direction. The dielectric layer corresponding to the third separation structure 960 separates the B-type first trench 130b and the B-type second trench 140b in the first direction.

Referring to FIG. 34, the step of patterning the target material layer 170 with the second spacers 810 and the third core layers 230 as a mask includes patterning the mask material layer 110 with the second spacers 810 and the third core layers 230 as the mask to form second pattern transfer layers 120.

The second pattern transfer layers 120 are used as an etching mask for patterning the target material layer 170.

In some embodiments, after forming the second pattern transfer layers 120, and before patterning the target material layer 170 with the second pattern transfer layers 120 as a mask, the method also includes removing the second spacers 810 and the third core layers 230 to prepare for patterning the target material layer 170 with the second pattern transfer layers 120 as a mask.

Referring to FIG. 35, the target material layer 170 is patterned with the second pattern transfer layers 120 as a mask.

The pattern of the second spacers 810 and the third core layers 230 is transferred to the target material layer 170 through the second pattern transfer layers 120, which is beneficial to improve the pattern transfer accuracy, so that the size accuracy of the first target structures 131 and the second target structures 141 is higher.

Optionally, an etching process is used to pattern the target material layer 170 with the second pattern transfer layers 120 as a mask. The second pattern transfer layers 120 are thinned in the step of patterning the target material layer 170. For example, a silicon oxide layer in the second pattern transfer layer 120 may be removed.

Referring to FIG. 36, after forming the first target structures 131 and the second target structures 141, the method also includes removing the second pattern transfer layers 120.

Removing the second pattern transfer layers 120 prepares for formation of the first metal lines and the second metal lines.

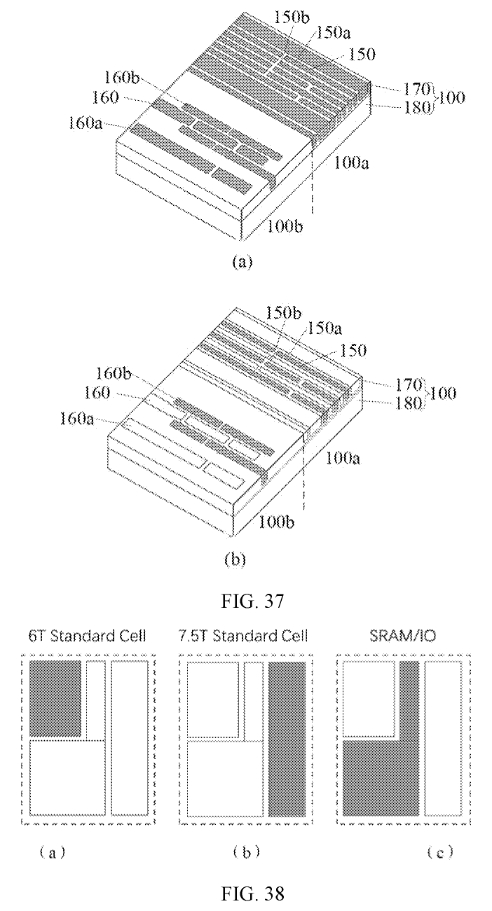

Referring to FIG. 37, after forming the first target structures 131 in the first area 100a and the second target structures 141 in the second area 100b, the method further includes forming first metal lines 150 in the first trenches 130, and forming second metal lines 160 in the second trenches 140.

The first metal lines 150 and the second metal lines 160 are metal interconnects in a back-end-of-line (BEOL) process.

Part (b) of FIG. 37 schematically distinguishes between different types of the first metal lines 150 and the second metal lines 160 shown at part (a) of FIG. 37.

Optionally, the first metal lines 150 may be divided into A-type first metal lines 150a (as shown by the black-filled first metal lines 150 in the first area 100a of part (b) in FIG. 37) and B-type first metal lines 150b (as shown by the white-filled first metal lines 150 in the first area 100a of part (b) in FIG. 37), which are arranged separately from each other. The A-type first metal lines 150a are metal lines corresponding to the second core layers 220 in the first area 100a. The B-type first metal lines 150b are metal lines corresponding to the trenches 950 surrounded by the second spacer material layer 800 of the second core layers 220 in the first area 100a.

Similarly, the second metal lines may also be divided into A-type second metal lines 160a (as shown by the white-filled second metal lines 160 in the second area 100b of part (b) in FIG. 37) and B-type second metal lines 160b (as shown by the black-filled second metal lines 160 in the second area 100b of part (b) in FIG. 37). The A-type second metal lines 160a are the metal lines corresponding to the third core layers 230 corresponding to the third protective layer openings 760, and the B-type second metal lines 160b are the metal lines corresponding to the trenches 950 surrounded by the second spacer material layer 800 on sidewalls of the third core layers 230. The A-type second metal lines 160a and the B-type second metal lines 160b may be arranged separately from each other, and the width, length, and pitch between them may be adjusted, offering greater design freedom compared to the first metal lines 150.

Correspondingly, in some embodiments, the dielectric layer corresponding to the first separation structures 930 separates the A-type first metal lines 150a along the first direction. The dielectric layer corresponding to the second separation structures 940 separates the A-type second metal lines 160a along the first direction. The dielectric layer corresponding to the third separation structures 960 separates the B-type first metal lines 150b and B-type second metal lines 160b along the first direction.

A dielectric layer is an inter metal dielectric (IMD) layer. The dielectric layer is used to achieve electrical isolation between metal interconnect lines in a BEOL process.

Exemplarily, as shown in FIG. 38, formation methods for some embodiments are illustrated. A 6T standard cell area, a 7.5T standard cell area, and an SRAM/input-output area (SRAM/IO) are formed over the base. The black area marks a corresponding device area.

Optionally, in the 6T standard cell area at part (a) of FIG. 38, the metal pitch reaches about 30 nm, and uniform metal lines for routing and wider power rails are required. Thus, SAQP may be used in the formation process. In the 7.5T standard cell area at part (b) of FIG. 38, the metal pitch is around 40 nm, and uniform metal lines for routing and wider power rails are required. Thus, SALELE may be used in the formation process. In the SRAM/IO area at part (c) of FIG. 38, the metal pitch is larger than 50 nm, and there are no clear layout rules for metal routing. Thus, SALELE may be used in the formation process. Therefore, by combining SAQP and SALELE, the 6T standard cell areas, 7.5T standard cell areas, and SRAM/IO areas that have different pitch requirements may be achieved over the same base.

Although the present disclosure is illustrated as above, the present disclosure is not limited thereto. Any person skilled in the art may make various changes and modifications without departing from the spirit and scope of the present disclosure. Therefore, the protection scope of the present disclosure should be subject to the scope defined by the claims.

What is claimed is:

1. A method for fabricating a semiconductor structure, comprising:
providing a base, wherein the base includes a substrate and a target material layer on the substrate, a second core material layer is formed over the base, the base further includes a first area for forming a plurality of first target structures, and a second area for forming a plurality of second target structures, the plurality of first target structures and the plurality of second target structures extend along a first direction, and a pitch of adjacent first target structures of the plurality of first target structures is less than or equal to a pitch of adjacent second target structures of the plurality of second target structures;
forming a first protective layer covering the second core material layer in the first area;
using the first protective layer as a mask to modify the second core material layer in the second area and forming a third core material layer having an etching selectivity ratio with a remaining portion of the second core material layer in the first area;
removing the first protective layer;
forming a first core material layer covering the second core material layer and the third core material layer;
patterning the first core material layer and forming a plurality of first core layers that are separate in the first area, wherein the plurality of first core layers extend along the first direction and are arranged in parallel along the second direction, and the first direction is perpendicular to the second direction;
forming a plurality of first spacers covering sidewalls of the plurality of first core layers;
removing the plurality of first core layers;
forming a second protective layer on the third core material layer in the second area, wherein the second protective layer is formed with a plurality of second protective layer openings that are separate, extend along the first direction, and are arranged in parallel along the second direction;
using the plurality of first spacers and the second protective layer for masking to pattern the second core material layer and the third core material layer, and forming a plurality of second core layers corresponding to the second core material layer, a plurality of third core layers corresponding to the third core material layer, and a plurality of third core layer openings corresponding to the plurality of second protective layer openings in the plurality of third core layers;
removing the plurality of first spacers and the second protective layer;
forming a plurality of second spacers covering sidewalls of the plurality of second core layers and the plurality of third core layers;
forming a third protective layer covering the plurality of second core layers, the plurality of third core layers, and the plurality of second spacers, wherein the third protective layer is formed with a plurality of third protective layer openings that are separate, extend along the first direction, and are arranged in parallel along the second direction, the third protective layer fills the plurality of third core layer openings, and the plurality of third protective layer openings expose the plurality of third core layers;
patterning the plurality of third core layers with the third protective layer for masking;
removing the third protective layer;
removing the plurality of second core layers; and
patterning the target material layer with the plurality of second spacers and the plurality of third core layers for masking and forming the plurality of first target structures in the first area and the plurality of second target structures in the second area.

2. The method for forming the semiconductor structure according to claim 1, wherein:
in a step of providing the base, the target material layer is a dielectric layer, the plurality of first target structures are a plurality of first trenches, and the plurality of second target structures are a plurality of second trenches;
in a step of patterning the target material layer using the plurality of second spacers and the plurality of third core layers for masking, the dielectric layer is patterned using the plurality of second spacers and the plurality of third core layers for masking to form the plurality of first trenches and the plurality of second trenches in the dielectric layer; and
after forming the plurality of first target structures in the first area and the plurality of second target structures in the second area, the method according to claim 1 further comprises:
forming a plurality of first metal lines in the plurality of first trenches; and
forming a plurality of second metal lines in the plurality of second trenches.

3. The method for forming the semiconductor structure according to claim 1, wherein:
in a step of providing the base, the first area includes a logic device area, and the second area includes a peripheral device area; and
a thickness of a gate oxide layer in the logic device area is less than a thickness of a gate oxide layer in the peripheral device area.

4. The method for forming the semiconductor structure according to claim 1, wherein:
the pitch of the adjacent first target structures of the plurality of first target structures is 24 nm to 38 nm; and
the pitch of the adjacent second target structures of the plurality of second target structures is 38 nm to 200 nm.

5. The method for forming the semiconductor structure according to claim 1, wherein a step of forming the first protective layer covering the second core material layer in the first area comprises:
forming a first protective material layer covering the second core material layer; and
removing the first protective material layer in the second area, and retaining a portion of the first protective material layer in the first area as the first protective layer.

6. The method for forming the semiconductor structure according to claim 1, wherein in a step of modifying the second core material layer in the second area using the first protective layer for masking, the second core material layer in the second area is ion implanted using the first protective layer for masking to form the third core material layer having the etching selectivity ratio with the remaining portion of the second core material layer.

7. The method for forming the semiconductor structure according to claim 6, wherein:
in a step of providing the base, a material of the second core material layer includes one or more of amorphous silicon, polycrystalline silicon, single crystal silicon, silicon oxide, advanced patterned film materials, spin-on carbon, and silicon carbide; and
in a step of performing ion implantation in the second core material layer in the second area using the first protective layer for masking, ions implanted by the ion implantation include one or more of boron, phosphorus, arsenic, boron chloride, boron dichloride, and carbon.

8. The method for forming the semiconductor structure according to claim 1, wherein:
a step of patterning the first core material layer includes forming a plurality of first mask layers that are separate, on the first core material layer, and in the first area;
the first core material layer is patterned using the plurality of first mask layers, the plurality of first core layers are formed, and the plurality of first core layers are separate in the first area; and
after the plurality of first core layers are formed, the plurality of first mask layers are removed.

9. The method for forming the semiconductor structure according to claim 1, wherein a step of forming the plurality of first spacers covering the sidewalls of the plurality of first core layers comprises:
forming a first spacer material layer covering the sidewall and tops of the plurality of first core layers and above the second core material layer; and
removing portions of the first spacer material layer on the tops of the first core layers and above the second core material layer, and retaining portions of the first spacer material layer on the sidewalls of the plurality of first core layers as the plurality of first spacers.

10. The method for forming the semiconductor structure according to claim 1, wherein a step of forming the second protective layer on the third core material layer in the second area comprises:
forming a second protective material layer covering the second core material layer, the third core material layer, and the plurality of first spacers; and
patterning the second protective material layer, removing the second protective material layer in the first area, removing a plurality of portions of the second protective material layer that extend along the first direction and the second direction in the second area, and retaining a plurality of remaining portions of the second protective material layer in the second area as the second protective layer.

11. The method for forming the semiconductor structure according to claim 1, wherein in a step of forming the second protective layer on the third core material layer in the second area, a size of the plurality of second protective layer openings along the second direction is 35 nm to 200 nm, and a pitch of the plurality of second protective layer openings along the second direction is 76 nm to 200 nm.

12. The method for forming the semiconductor structure according to claim 1, wherein:
before forming the first core material layer covering the second core material layer and the third core material layer, the method according to claim 1 further includes forming an etch stop layer covering the second core material layer and the third core material layer;
in a step of forming the first core material layer covering the second core material layer and the third core material layer, the first core material layer covers the etch stop layer;
before forming the second protective layer on the second core material layer in the second area, the method according to claim 1 further includes patterning the etch stop layer using the plurality of first spacers for masking and forming a first pattern transfer layer;
in a step of patterning the second core material layer and the third core material
layer using the plurality of first spacers and the second protective layer for masking, the second core material layer in the first area is patterned using the first pattern transfer layer for masking to form the plurality of second core layers that are separate in the first area; and
after forming the plurality of second core layers and the plurality of third core layers, the first pattern transfer layer is removed.

13. The method for forming the semiconductor structure according to claim 1, wherein a step of forming the plurality of second spacers covering the sidewalls of the second core layers and the plurality of third core layers comprises:
forming a second spacer material layer covering the sidewalls and tops of the plurality of second core layers and the plurality of third core layers, and a top of the base; and
removing portions of the second spacer material layer on the tops of the plurality of second core layers and the plurality of third core layers, and the top of the base, and retaining portions of the second spacer material layer on the sidewalls of the plurality of second core layers and the plurality of third core layers as the plurality of second spacers.

14. The method for forming the semiconductor structure according to claim 1, wherein a step of forming the third protective layer covering the plurality of second core layers, the plurality of third core layers, and the plurality of second spacers comprises:
forming a third protective material layer covering the plurality of second core layers, the plurality of third core layers, and the plurality of second spacers; and
patterning the third protective material layer, removing a plurality of portions of the third protective material layer extending in the first direction and the second direction in the second area, and retaining a plurality of remaining portions of the third protective material layer as the third protective layer.

15. The method for forming the semiconductor structure according to claim 1, wherein in a step of forming the third protective layer covering the plurality of second core layers, the plurality of third core layers, and the plurality of second spacers, a size of the plurality of third protective layer openings along the second direction is 35 nm to 200 nm, and a pitch of the plurality of third protective layer openings along the second direction is 76 nm to 200 nm.

16. The method for forming the semiconductor structure according to claim 1, wherein:
the plurality of second core layers are removed by a wet etching process; and
an etching solution of the wet etching process includes one or more of a potassium hydroxide (KOH) solution, a 2,4,5-trihydroxymethamphetamine (THMA) solution, and a standard clean 1 (SC1) solution.

17. The method for forming the semiconductor structure according to claim 1, wherein:
in a step of providing the base, a mask material layer is formed between the target material layer and the second core material layer;
a step of patterning the target material layer using the plurality of second spacers and the plurality of third core layers for masking comprises patterning the mask material layer using the plurality of second spacers and the plurality of third core layers for masking and forming a second pattern transfer layer;
the target material layer is patterned using the second pattern transfer layer for masking; and
after the plurality of first target structures and the plurality of second target structures are formes, the second pattern transfer layer is removed.

18. The method for forming the semiconductor structure according to claim 17, wherein after forming the second pattern transfer layer and before patterning the target material layer using the second pattern transfer layer for masking, the plurality of second spacers and the plurality of third core layers are removed.

19. The method for forming the semiconductor structure according to claim 1, wherein:
after removing the plurality of first spacers and the second protective layer, and before forming the plurality of second spacers covering the sidewalls of the plurality of second core layers and the plurality of third core layers, the method according to claim 1 further includes patterning part of the plurality of second core layers in the first area and part of the plurality of third core layers in the second area, forming a first separation opening that cuts off one of the plurality of second core layers in the first area in the first direction and a second separation opening that cuts off one of the plurality of third core layers in the second area in the first direction;
in a step of forming the plurality of second spacers covering the sidewalls of the plurality of second core layers and the plurality of third core layers, the plurality of second spacers also cover sidewalls of the first separation opening and sidewalls of the second separation opening, portions of the plurality of second spacers on opposite sidewalls of the first separation opening are in contact with each other to form a first separation structure, and portions of the plurality of second spacers on opposite sidewalls of the second separation opening are in contact with each other to form a second separation structure; and
in a step of patterning the target material layer using the plurality of second spacers and the plurality of third core layers for masking to form the plurality of first target structures in the first area and the plurality of second target structures in the second area, the target material layer is patterned using the first separation structure and the second separation structure for masking, a portion of the target material layer is obtained that corresponds to the first separation structure and separates two of the plurality of first target structures in the first direction, and another portion of the target material layer is obtained that corresponds to the second separation structure and separates two of the plurality of second target structures in the first direction.

20. The method for forming the semiconductor structure according to claim 13, wherein:
in a step of forming the second spacer material layer covering the sidewalls and tops of the plurality of second core layers and the plurality of third core layers, and the top of the base, a trench is formed by portions of the second spacer material layer on opposite sidewalls of the plurality of second core layers or the plurality of third core layers;
after forming the second spacer material layer covering the sidewalls and tops of the plurality of second core layers and the plurality of third core layers, and the top of the base, and before removing the second spacer material layer on the tops of the plurality of second core layers and the plurality of third core layers, and the top of the base, a third separation structure is formed that extends along the second direction and contacts at least one of the plurality of the second spacers in the trench in the first area or the second area, the third separation structure separates the trench in the first direction; and
in a step of patterning the target material layer using the plurality of second spacers and the plurality of third core layers for masking to form the plurality of first target structures in the first area and the plurality of second target structures in the second area, the target material layer is patterned using the third separation structure for masking, a portion of the target material layer is obtained that corresponds to the third separation structure and separates the first target structure or the second target structure in the first direction.
